(19) United States
(12) Patent Application Publication
(10) Pub. No.: US 2008/0241377 A1
(43) Pub. Date: Oct. 2, 2008

(54) VAPOR DEPOSITION SYSTEM AND METHOD OF OPERATING

(75) Inventor: JACQUES FAGUET, Albany, NY (US)

Correspondence Address: DLA PIPER US LLP, P. O. BOX 9271, RESTON, VA, 20195, US

(73) Assignee: TOKYO ELECTRON LIMITED, TOKYO (JP)

(21) Appl. No.: 11/693,067

(22) Filed: Mar. 29, 2007

(51) Int. Cl. B05C 11/02; C23C 16/00

(52) U.S. Cl. 427/248.1; 118/724; 118/58

(57) ABSTRACT

A method and system for depositing a thin film on a substrate using a vapor deposition process is described. The processing system comprises a process chamber having a pumping system configured to evacuate the process chamber, a substrate holder coupled to the process chamber and configured to support the substrate, and a gas distribution system coupled to the process chamber and configured to introduce a film forming composition to a process space in the vicinity of a surface of the substrate. Furthermore, a heat source is coupled to the gas distribution system, wherein the heat source comprises one or more heating elements coupled to a power source, and wherein the one or more heating elements are disposed on an interior surface of the gas distribution system or embedded within the gas distribution system or both, and configured to interact with the firm forming composition and cause pyrolysis of one or more constituents of the film forming composition when heated.

### BACKGROUND OF THE INVENTION

1. Field of Invention

The present invention relates to a method and system for thin film deposition, and more particularly to a method and system for depositing a thin film, using a vapor deposition process.

2. Description of Related Art

During material processing, such as semiconductor device manufacturing for production of integrated circuits (ICs), vapor deposition is a common technique to form thin films, as well as to form conformal thin films over and within complex topography on a substrate. Vapor deposition processes can include chemical vapor deposition (CVD) and plasma enhanced CVD (PECVD). For example, in semiconductor manufacturing, such vapor deposition processes may be used for gate dielectric film formation in front-end-of-line (FEOL) operations, and low dielectric constant (low-k) or ultra-low-k, porous or non-porous, dielectric film formation and barrier/seed layer formation for metallization in back-end-of-line (BEOL) operations, as well as capacitor dielectric film formation in DRAM production.

In a CVD process, a continuous stream of film precursor vapor is introduced to a process chamber containing a substrate, wherein the composition of the film precursor has the principal atomic or molecular species found in the film to be formed on substrate. During this continuous process, the precursor vapor is chemisorbed on the surface of the substrate while it thermally decomposes and reacts with or without the presence of an additional gaseous component that assists the reduction of the chemisorbed material, thus, leaving behind the desired film.

In a PECVD process, the CVD process further includes plasma that is utilized to alter or enhance the film deposition mechanism. For instance, plasma excitation can allow film-forming reactions to proceed at temperatures that are significantly lower than those typically required to produce a similar film by thermally excited CVD. In additions plasma excitation may activate film-forming chemical reactions that are not energetically or kinetically favored in thermal CVD.

Other CVD techniques include hot-filament CVD (otherwise known as hot-wire CVD or pyrolytic CVD). In hot-filament CVD, a firm precursor is thermally decomposed by a resistively heated filament, and the resulting fragmented molecules adsorb and react on the surface of the substrate to leave the desired film. Unlike PECVD, hot-filament CVD does not require formation of plasma.

### SUMMARY OF THE INVENTION

A method and system are provided for depositing a thin firm using chemical vapor deposition (CVD).

Furthermore, a method and system are provided for depositing a thin film using pyrolytic CVD, whereby a resistive film heating element disposed on an interior surface of a gas distribution system is utilized to pyrolize a film forming composition.

According to one embodiment, a processing system for depositing a thin film on a substrate using chemical vapor deposition (CVD) is described. The processing system comprises a process chamber having a pumping system configured to evacuate the process chamber. A substrate holder is coupled to the process chamber and configured to support the substrate. A gas distribution system is coupled to the process chamber and configured to introduce a film forming composition to a process space in the vicinity of a surface of the substrate. A heat source is coupled to the gas distribution system. The heat source comprises one or more heating elements coupled to a power source. The one or more heating elements are disposed on an interior surface of the gas distribution system or embedded within the gas distribution system or both, and configured to interact with the film forming composition and cause pyrolysis of one or more constituents of the film forming composition when heated.

According to another embodiment, a method of depositing a thin film on a substrate is described. A substrate is provided on a substrate holder in a process chamber of a deposition system. A film forming composition is provided to a gas distribution system located above the substrate and opposing an upper surface of the substrate. One or more constituents of the film forming composition is pyrolized using one or more heating elements disposed on an interior surface of the gas distribution system. The substrate is exposed to the film forming composition in the process chamber.

### BRIEF DESCRIPTION OF THE DRAWINGS

In the accompanying drawings:

FIG. 1 depicts a schematic view of a deposition system according to an embodiment;

FIG. 2A depicts a gas distribution system according to an embodiment;

FIG. 2B depicts a too view of a gas distribution plate according to another embodiment;

FIG. 2C depicts a top view of a gas distribution plate according to another embodiment;

FIG. 2D depicts a top view of a gas distribution plate according to another embodiment;

FIG. 2E depicts an exploded view of an opening in a member of a gas distribution system according to another embodiment;

FIG. 2F depicts an exploded view of an opening in a member of a gas distribution system according to yet another embodiment;

FIG. 3 depicts a gas distribution system according to another embodiment;

FIG. 4A depicts a gas distribution system according to another embodiment;

FIG. 4B depicts a gas distribution system according to another embodiment;

FIG. 5 depicts a gas distribution system according to another embodiment;

FIG. 6 depicts a gas distribution system according to another embodiment:

FIG. 7 provides a cross-sectional view of a resistive film heating element according to an embodiment; and

FIG. 8 illustrates a method of depositing a thin film on a substrate according to yet another embodiment.

### DETAILED DESCRIPTION OF SEVERAL EMBODIMENTS

In the following description, in order to facilitate a thorough understanding and for purposes of explanation and not limitation, specific details are set forth, such as a particular geometry of the deposition system and descriptions of various components. However, it should be understood that the invention may be practiced in other embodiments that depart from these specific details.

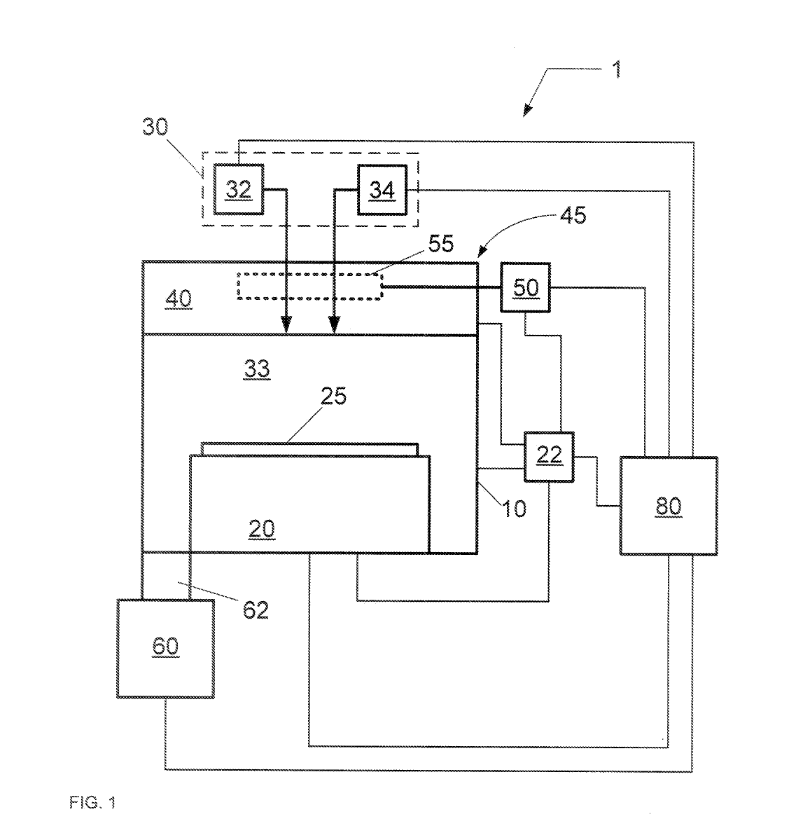

Referring now to the drawings, wherein like reference numerals designate identical or corresponding parts throughout the several views, FIG. 1 schematically illustrates a deposition system 1 for depositing a thin film, such as a conductive film, a non-conductive film, or a semi-conductive film. For example, the thin film can include a dielectric film, such as a low dielectric constant (low-k) or ultra-low-k dielectric film. Deposition system 1 can include a chemical vapor deposition (CVD) system, whereby a film forming composition is thermally activated or decomposed in order to form a film on a substrate. For example, the deposition system 1 comprises a pyrolytic CVD system.

The deposition system 1 comprises a process chamber 10 having a substrate holder 20 configured to support a substrate 25, upon which the thin film is formed. Furthermore, the substrate holder is configured to control the temperature of the substrate at a temperature suitable for the film forming reactions.

The process chamber 10 is coupled to a film forming composition delivery system 30 configured to introduce a film forming composition to the process chamber 10 through a gas distribution system 40. Furthermore, a heat source 45 is coupled to the gas distribution system 40 and configured to chemically modify the film forming composition. The heat source 45 comprises one or more heating elements 55 disposed on an interior surface of the gas distribution system 40 or embedded within the gas distribution system 40 or both, and a power source 50 that is coupled to the one or more heating elements 55 and that is configured to deliver electrical power to the one or more heating elements 55. For example, the one or more heating elements 55 can comprise one or more resistive heating elements. When electrical current flows through and effects heating of the one or more resistive heating elements, the interaction of these heated elements with the film forming composition causes pyrolysis of one or more constituents of the film forming composition.

The process chamber 10 is further coupled to a vacuum pumping system 60 through a duct 62, wherein the vacuum pumping system 60 is configured to evacuate the process chamber 10 and the gas distribution system 40 to a pressure suitable for forming the thin film on the substrate 25 and suitable for pyrolysis of the film forming composition.

The film forming composition delivery system 30 can include one or more material sources configured to introduce a film forming composition to the gas distribution system 40. For example, the film forming composition may include one or more gases, or one or more vapors formed in one or more gases, or a mixture of two or more thereof. The film forming composition delivery system 30 can include one or more gas sources, or one or more vaporization sources, or a combination thereof. Herein vaporization refers to the transformation of a material (normally stored in a state other than a gaseous state) from a non-gaseous state to a gaseous state. Therefore, the terms “vaporization,” “sublimation” and “evaporation” are used interchangeably herein to refer to the general formation of a vapor (gas) from a solid or liquid precursor, regardless of whether the transformation is, for example, from solid to liquid to gas, solid to gas; or liquid to gas.

When the film forming composition is introduced to the gas distribution system 40, one or more constituents of the film forming composition are suspected to pyrolysis by the heat source 45 described above. The film forming composition can include film precursors that may or may not be fragmented by pyrolysis in the gas distribution system 40. The film precursor or precursors may include the principal atomic or molecular species of the film desired to be produced on the substrate. Additionally, the film forming composition can include a reducing agent that may or may not be fragmented by pyrolysis in the gas distribution system 40. The reducing agent or agents may assist with the reduction of a film precursor on substrate 25. For instance, the reducing agent or agents may react with a part of or all of the film precursor on substrate 25. Additionally yet, the film forming composition can include a polymerizing agent that may or may not be fragmented by pyrolysis in the gas distribution system 40. The polymerizing agent may assist with the polymerization of a film precursor or fragmented film precursor on substrate 25.

According to one example, when forming a copolymer thin film on substrate 25, a film forming composition comprising two or more monomer gases is introduced to the gas distribution system 40 and is exposed to the heat source 45, i.e., the one or more heating elements 55, having a temperature sufficient to pyrolyze one or more of the monomers and produce a source of reactive species. These reactive species are introduced to and distributed within process space 33 in the vicinity of the upper surface of substrate 25. Substrate 25 is maintained at a temperature lower than that of the heat source 45 in order to condensate and induce polymerization of the chemically altered film forming composition at the upper surface of substrate 25. As another example, when forming a fluorocarbon-organosilicon copolymer, monomer gases of a fluorocarbon precursor and organosilicon precursor are used.

Further yet, the film forming composition can include an initiator that may or may not be fragmented by pyrolysis in the gas distribution system 40. An initiator or fragmented initiator may assist with the fragmentation of a film precursor, or the polymerization of a film precursor. The use of an initiator can permit higher deposition rates at lower heat source temperatures. For instance, the one or more heating elements can be used to fragment the initiator to produce radical species of the initiator (i.e., a fragmented initiator) that are reactive with one or more of the remaining constituents in the film forming composition. Furthermore, for instance, the fragmented initiator or initiator radicals can catalyze the formation of radicals of the film forming composition. For example, when forming a fluorocarbon-organosilicon copolymer, the initiator can be perfluorooctane sulfonyl fluoride (PFOSF) used In the polymerization of a cyclic vinylmethylsiloxane, such as 1,3,5-trivinyl-1,3,5-trimethrylcyclotrisiloxane (V₃D₃).

According to one embodiment, the film forming composition delivery system 30 can include a first material source 32 configured to introduce one or more film precursors to the gas distribution system 40, and a second material source 34 configured to introduce a (chemical) initiator to the gas distribution system 40 Furthermore, the film forming gas delivery system 30 can include additional gas sources configured to introduce an inert gas, a carrier gas or a dilution gas. For example, the inert gas, carrier gas or dilution gas can include a noble gas, i.e., He, Ne, Ar, Kr, Xe, or Rn.

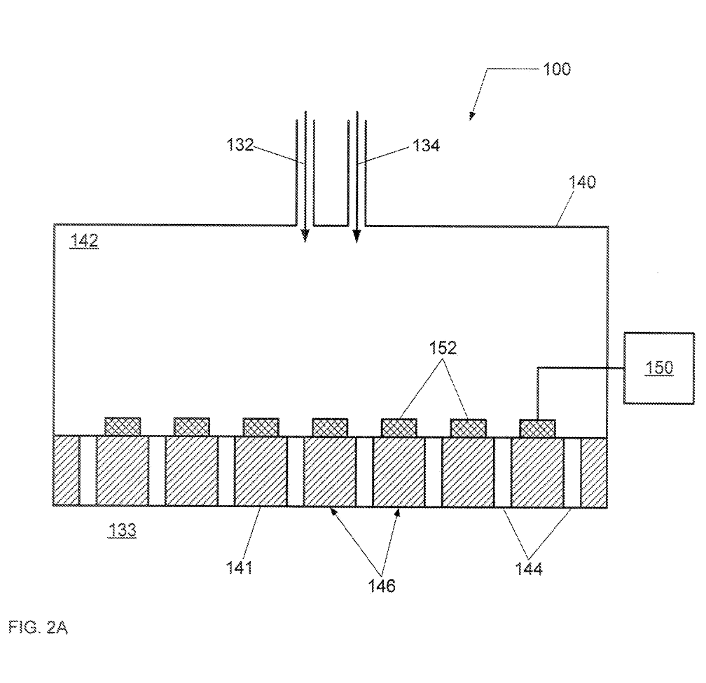

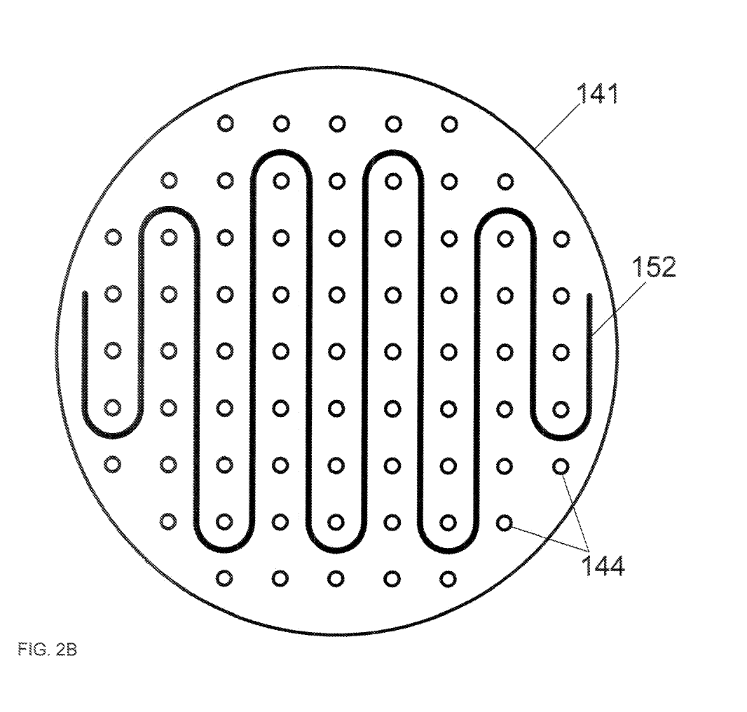

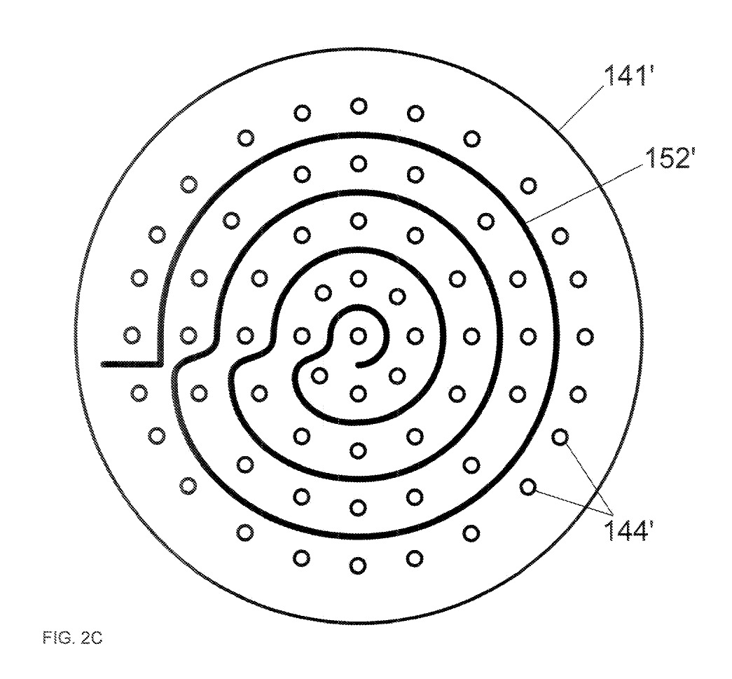

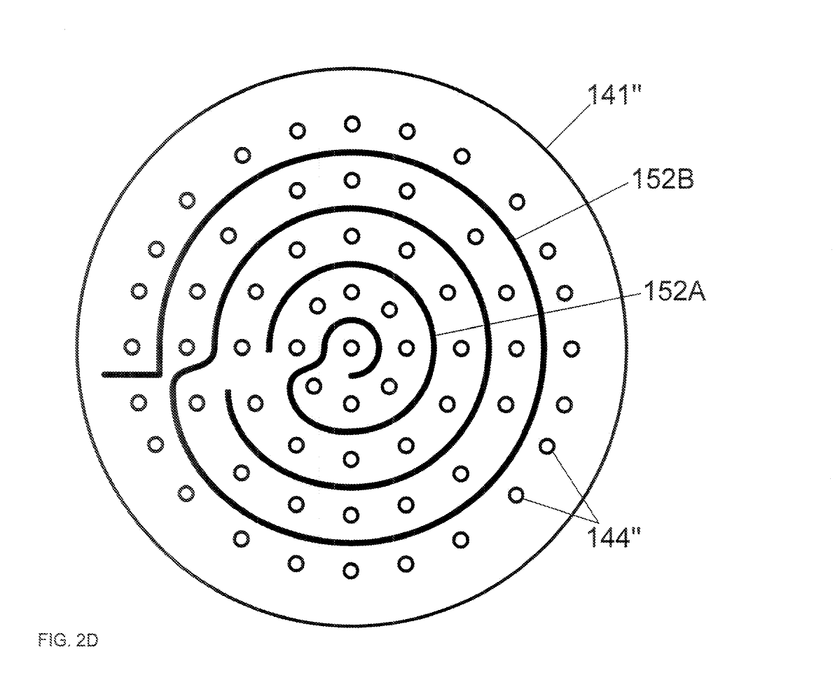

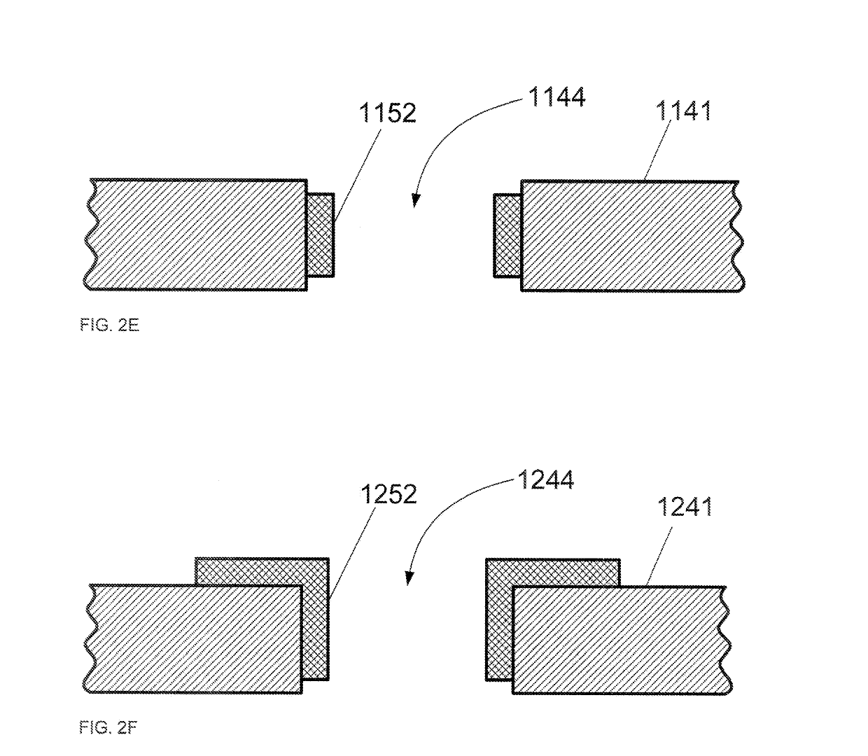

Referring now to FIG. 2A, a gas distribution system 100 is illustrated according to an embodiment. The gas distribution system 100 comprises a housing 140 configured to be coupled to or within a process chamber of a deposition system (such as process chamber 10 of deposition system 1 in FIG. 1), and a gas distribution plate 141 configured to be coupled to the housing 140, wherein the combination form a plenum 142. The gas distribution system 100 may be thermally insulated from the process chamber, or it may not be thermally insulated from the process chamber. The gas distribution system 100 is configured to receive a film forming composition into the plenum 142 from a film forming composition delivery system (not shown) and distribute the film forming composition in the process chamber. For example, the gas distribution system 100 can be configured to receive one or more constituents of a film forming composition 132 and an optional initiator 134 into plenum 142 from the film forming composition delivery system. The one or more constituents of the film forming composition 132 and the optional initiator 134 may be introduced to plenum 142 separately as shown, or they may be introduced through the same opening. The gas distribution plate 141 comprises a plurality of openings 144 arranged to introduce and distribute the film forming composition from plenum 142 to a process space 133 proximate a substrate (not shown) upon which a film is to be formed. For example, gas distribution plate 141 comprises a lower surface 146 configured to face the upper surface of a substrate.

Furthermore, the gas distribution system 100 comprises a heat source having one or more heating elements 152 coupled to a power source 150. The one or more heating elements 152 are disposed on at least one interior surface of the gas distribution system 100, such that they may interact with any constituent of the film forming composition, or all of the constituents of the film forming composition including the optional initiator. For example, the one or more heating elements 152 may be formed on an upper surface of the gas distribution plate 141. Additionally, for example, the one or more heating elements 152 can comprise one or more resistive heating elements. When the power source 150 couples electrical power to the one or more heating elements 152, the one or more heating elements 152 may be elevated to a temperature sufficient to pyrolize one or more constituents of the film forming composition Power source 150 may include a direct current (DC) power source, or it may include an alternating current (AC) power source.

The one or more openings 144 formed in gas distribution plate 141 can include one or more orifices or one or more slots or a combination thereof. The one or more openings 144 can include a plurality of orifices distributed on the gas distribution plate 141 in a rectilinear pattern. Alternatively, the one or more openings 144 can include a plurality of orifices distributed on the gas distribution plate 141 in a circular pattern (e.g., orifices are distributed in a radial direction or angular direction or both). When the one or more heating elements 152 are disposed on the upper surface of the gas distribution plate 141, each heating element can be positioned such that it does not overlap with an opening, or it can be positioned such that it does overlap with an opening and the opening is formed there through. For example, a rectilinear distribution of openings 144 may be used while each heating element 152 takes a serpentine-like path on gas distribution plate 141 as illustrated in FIG. 2B. Alternatively, for example, a circular distribution of openings 144′ may be used while each heating element 152′ takes a spiral-like path on gas distribution plate 141′ as illustrated in FIG. 2C.

Additionally, the plurality of openings 144 can be distributed in various density patterns on the gas distribution plate 141. For example, more openings can be formed near the center of the gas distribution plate 141 and fewer openings can be formed near the periphery of the gas distribution plate 141. Alternatively, for example, more openings can be formed near the periphery of the gas distribution slate 141 and fewer openings can be formed near the center of the gas distribution plate 141. Additionally yet, the size of the openings can vary on the gas distribution plate 141. For example, larger openings can be formed near the center of the gas distribution plate 141 and smaller openings can be formed near the periphery of the gas distribution plate 141. Alternatively, for example, smaller openings -an be formed near the periphery of the gas distribution plate 141 and larger openings can be formed near the center of the gas distribution plate 141.

As illustrated in FIG, 2D, the one or more heating elements comprise a plurality of heating elements. For example, the plurality of heating elements include an inner heating element 152A and an outer heating element 152B coupled to a surface of a gas distribution plate 141″ having a plurality of openings 144″. In this example, the inner heating element 252A and the outer heating element 252B are concentric. However, the arrangement of the heating elements on the interior of the gas distribution system can be arbitrary and tailored for optimum process results. Power from a power source (not shown) may be coupled to the plurality of heating elements in series or in parallel or a combination thereof.

As described above, the one or more heating elements 152 are disposed on at least one interior surface of the gas distribution system 100, such that they may interact with any constituent of the film forming composition, or all of the constituents of the film forming composition including the optional initiator. An interior surface on the gas distribution system 100 can include any surface on the gas distribution system 100. As shown in FIG. 2A, an interior surface can include the upper surface of gas distribution plate 141. However, the interior surface can further include a surface on housing 140 or within plenum 142 that interacts with the film forming composition, or an internal surface of the inlet lines that provide the film forming composition 132 and the optional initiator 134 into plenum 142. Additionally, the one or more heating elements can be formed within any component of the gas distribution system 100 including, for example, the housing 140 and the gas distribution plate 141.

Furthermore, as illustrated in FIGS. 2E and 2F, the one or more heating elements can be coupled to a surface of the plurality of openings formed in gas distribution plate. For example, as illustrated in FIG. 2E, a heating element 1152 can be disposed on a surface of an opening 1144 formed in gas distribution plate 1141. Alternatively, for example, as illustrated in FIG. 2F, a heating element 1252 can be partially disposed on a surface of an opening 1244 formed in gas distribution plate 1241, as well as partially on an upper surface of gas distribution plate 1241 and/or a lower surface of gas distribution plate 1241 (not shown).

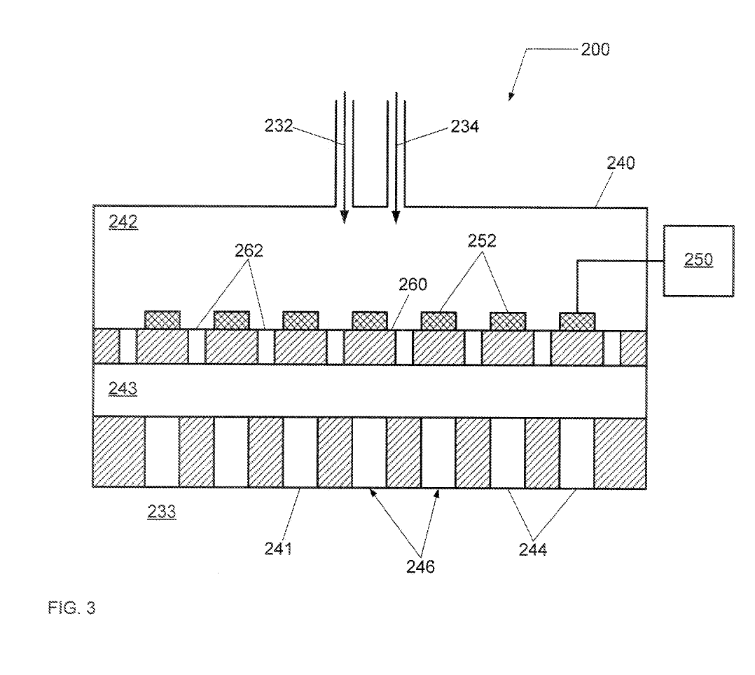

Referring now to FIG. 3, a gas distribution system 200 is illustrated according to another embodiment. The gas distribution system 200 comprises a housing 240 configured to be coupled to or within a process chamber of a deposition system (such as process chamber 10 of deposition system 1 in FIG. 1), and a gas distribution plate 241 configured to be coupled to the housing 240. The gas distribution system 200 may be thermally insulated from the process chamber, or it may not be thermally insulated from the process chamber. Additionally, gas distribution system 200 comprises an intermediate gas distribution plate 260 coupled to housing 240 such that the combination of housing 240, intermediate gas distribution plate 260 and gas distribution plate 241 form a plenum 242 above intermediate gas distribution plate 260 and an intermediate plenum 243 between the intermediate gas distribution plate 260 and the gas distribution plate 241, as shown in FIG. 3. The gas distribution system 200 is configured to receive a film forming composition into the plenum 242 from a film forming composition delivery system not shown) and distribute the film forming composition in the process chamber. For example, the gas distribution system 200 can be configured to receive one or more constituents of a film forming composition 232 and an optional initiator 234 into plenum 242 from the film forming composition delivery system. The one or more constituents of the film forming composition 232 and the optional initiator 234 may be introduced to plenum 242 separately as shown, or they may be introduced through the same opening.

Furthermore, the gas distribution system 200 comprises a heat source having one or more heating elements 252 coupled to a power source 250. The one or more heating elements 252 are disposed on at least one interior surface of the gas distribution system 200, such that they may interact with any constituent of the film forming composition or the optional initiator or both. For example, the one or more heating elements 252 may be formed on an upper surface of the intermediate gas distribution plate 260. The one or more heating elements 252 may be formed in a serpentine-like path, or a spiral-like path, or any arbitrary shape. Additionally, for example, the one or more heating elements 252 can comprise one or more resistive heating elements. When the power source 250 couples electrical power to the one or more heating elements 252, the one or more heating elements 252 may be elevated to a temperature sufficient to pyrolize one or more constituents of the film forming composition. Power source 250 may include a direct current (DC) power source, or it may include an alternating current (AC) power source.

The intermediate gas distribution plate 260 comprises a plurality of openings 262 arranged to distribute and introduce the film forming composition to the intermediate plenum 243. Additionally, the gas distribution plate 241 comprises a plurality of openings 244 arranged to introduce and distribute the film forming composition from the intermediate plenum 243 to a process space 233 proximate a substrate (not shown) upon which a film is to be formed. For example, gas distribution pate 241 comprises a lower surface 246 configured to face the upper surface of a substrate. The openings 262 in intermediate gas distribution plate 260 may or may not be aligned with the openings 244 in gas distribution plate 241.

Although the film forming composition is shown in FIG. 3 to be introduced to the plenum 241, any constituent of the film forming composition may be introduced directly to the intermediate plenum 243 in order to avoid or reduce interaction with the one or more heating elements 252 disposed in plenum 241. For example, the initiator may be introduced to plenum 241 in order to interact with the one or more heating elements 252 and undergo pyrolysis, while the remaining constituents of the film forming composition can be introduced to the intermediate plenum 243.

The one or more openings 244 formed in gas distribution plate 241 and the plurality of openings 262 formed in the intermediate gas distribution plate 260 can be arranged, distributed or sized as described above. When the one or more heating elements 252 are disposed on the upper surface of the intermediate gas distribution plate 260, each heating element can be positioned such that it does not overlap with an opening., or it can be positioned such that it does overlap with an opening and the opening is formed there through.

As described above, the one or more heating elements 252 are disposed on at least one interior surface of the gas distribution system 200, such that they may interact with any constituent of the film forming composition, or all of the constituents of the film forming composition including the optional initiator. An interior surface on the gas distribution system 200 can include any surface on the gas distribution system 200. As shown in FIG. 3, an interior surface can include the upper surface of intermediate gas distribution plate 260. However, the interior surface can further include a surface on housing 240 or within plenum 242 that interacts with the film forming composition, or a surface within plenum 243 that interacts with the film forming composition, or an internal surface of the inlet lines that provide the film forming composition 232 and the optional initiator 234 into plenum 242. Additionally, the interior surface can include the lower surface of intermediate gas distribution plate 260, a surface of the plurality of openings 262 formed in intermediate gas distribution plate 260, the upper surface of the gas distribution plate 241, the lower surface of the gas distribution plate 241, or a surface of the plurality of openings 244 formed in gas distribution plate 241, or a combination of two or more thereof. Furthermore, the one or more heating elements can be formed within any component of the gas distribution system 200 including, for example, the housing 240, the gas distribution plate 241 and the intermediate gas distribution plate 260.

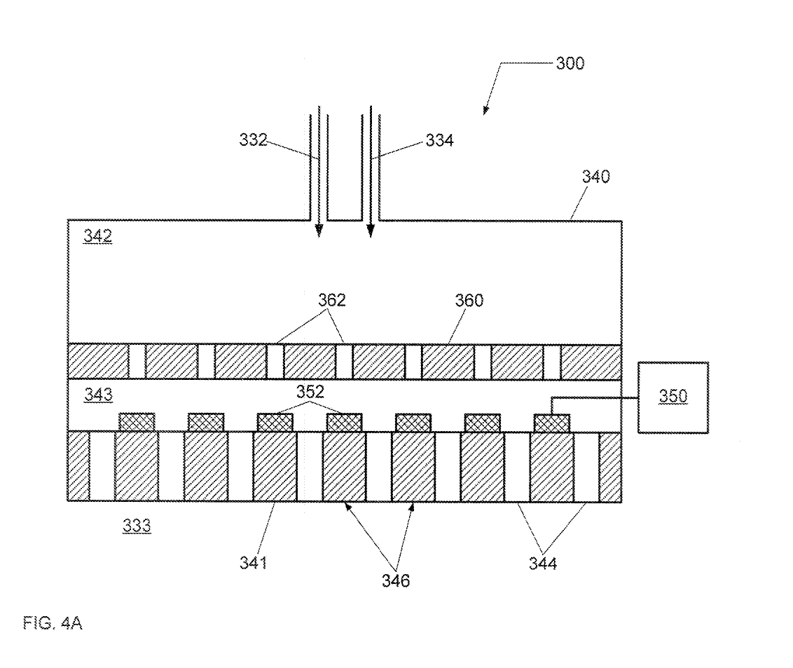

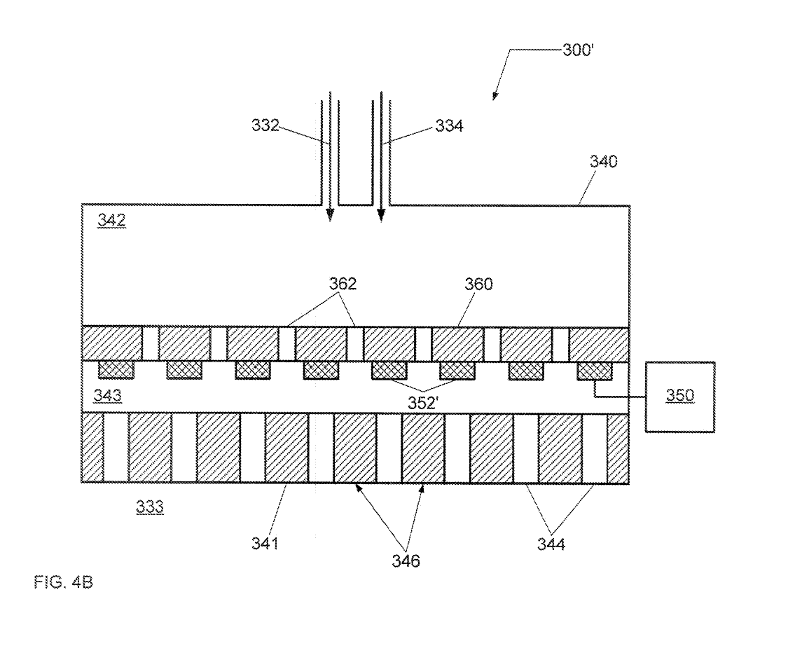

Referring now to FIG. 4A, a gas distribution system 300 is illustrated according to another embodiment. The gas distribution system 300 comprises a housing 340 configured to be coupled to or within a process chamber of a deposition system (such as process chamber 10 of deposition system 1 in FIG. 1), and a gas distribution plate 341 configured to be coupled to the housing 340. The gas distribution system 300 may be thermally insulated from the process chamber, or it may not be thermally insulated from the process chamber. Additionally, gas distribution system 300 comprises an intermediate gas distribution plate 360 coupled to housing 340 such that the combination of housing 340, intermediate gas distribution plate 360 and gas distribution plate 341 form a plenum 342 above intermediate gas distribution plate 360 and an intermediate plenum 343 between the intermediate gas distribution plate 360 and the gas distribution plate 341 as shown in FIG. 4A. The gas distribution system 300 is configured to receive a film forming composition into the plenum 342 from a film forming composition delivery system (not shown) and distribute the film forming composition in the process chamber. For example, the gas distribution system 300 can be configured to receive one or more constituents 332 of a film forming composition and an optional initiator 334 into plenum 342 from the film forming composition delivery system. The one or more constituents 332 of the film forming composition and the optional initiator 334 may be introduced to plenum 342 separately as shown, or they may be introduced through the same opening.

Furthermore, the gas distribution system 300 comprises a heat source having one or more heating elements 352 coupled to a power source 350. The one or more heating elements 352 are disposed on at least one interior surface of the gas distribution system 300, such that they may interact with the film forming composition. For example, the one or more heating elements 352 may be formed on an upper surface of the gas distribution plate 341. The one or more heating elements 352 may be formed in a serpentine-like path, or a spiral-like path, or any arbitrary shape. Additionally, for example, the one or more heating elements 352 can comprise one or more resistive heating elements. When the power source 350 couples electrical power to the one or more heating elements 352, the one or more heating elements 352 may be elevated to a temperature sufficient to pyrolize one or more constituents of the film forming composition. Power source 350 may include a direct current (DC) power source, or it may include an alternating current (AC) power source.

The intermediate gas distribution plate 360 comprises a plurality of openings 362 arranged to distribute and introduce the film forming composition to the intermediate plenum 343. Additionally, the gas distribution plate 341 comprises a plurality of openings 344 arranged to introduce and distribute the film forming composition from the intermediate plenum 343 to a process space 333 proximate a substrate (not shown) upon which a film is to be formed. For example, gas distribution plate 341 comprises a lower surface 346 configured to face the upper surface of a substrate. The openings 362 in intermediate gas distribution plate 360 may be arranged such that the flow of the film forming composition to intermediate plenum 343 impinges upon the one or more heating elements 352 as shown in FIG 4A.

The plurality of openings 344 formed in gas distribution plate 341 and the plurality of openings 362 formed in the intermediate gas distribution plate 360 can be arranged, distributed or sized as described above. When the one or more heating elements 352 are disposed on the upper surface of the gas distribution plate 341, each heating element can be positioned such that it does not overlap with an opening, or it can be positioned such that it does overlap with an opening and the opening is formed there through.

As described above, the one or more heating elements 352 are disposed on at least one interior surface of the gas distribution system 300, such that they may interact with any constituent of the film forming composition, or all of the constituents of the film forming composition including the optional initiator. An interior surface on the gas distribution system 300 can include any surface on the gas distribution system 300. As shown in FIG. 4A, an interior surface can include the upper surface of gas distribution plate 341. However, as illustrated in FIG. 4B, a gas distribution system 300′ can comprise one or more heating elements 352′ coupled to the lower surface of the intermediate gas distribution plate 360. Additionally, the interior surface can include a surface of the plurality of openings 362 formed in intermediate gas distribution plate 360, the upper surface of the gas distribution plate 341, the lower surface of the gas distribution plate 341, or a surface of the plurality of openings 344 formed in gas distribution plate 341, or a combination of two or more thereof. Furthermore, the one or more heating elements can be formed within any component of the gas distribution system 300 including, for example, the housing 340, the gas distribution plate 341 and the intermediate gas distribution plate 360.

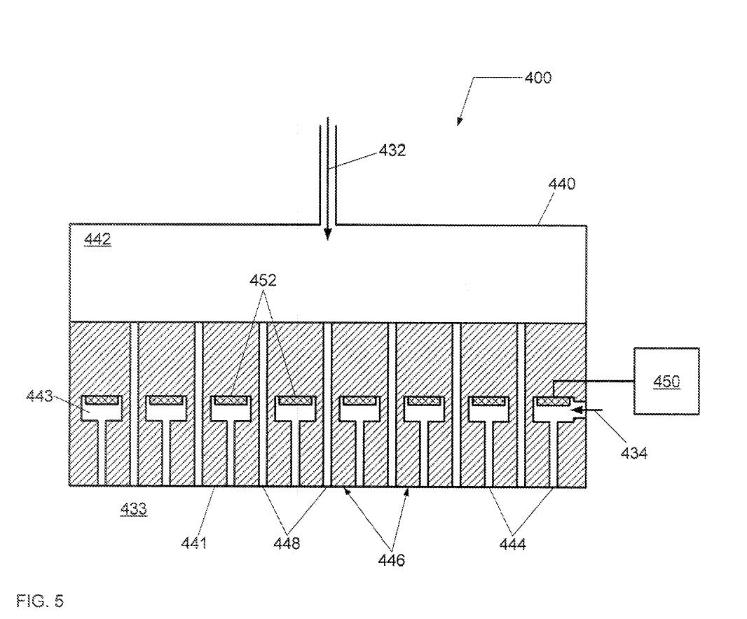

Referring now to FIG. 5, a gas distribution system 400 is illustrated according to another embodiment. The gas distribution system 400 comprises a housing 440 configured to be coupled to or within a process chamber of a deposition system (such as process chamber 10 of deposition system 1 in FIG. 1), and a multi-component gas distribution plate 441 configured to be coupled to the housing 440. The gas distribution system 400 may be thermally insulated from the process chamber, or it may not be thermally insulated from the process charmber. The multi-component gas distribution plate 441 is configured to independently couple a first composition 432 from a first plenum 442 through a first array of openings 448 to a process space 433 and a second composition 434 from a second plenum 443 through a second array of openings 444 to the process space 433 without mixing the first composition 432 and the second composition 434 prior to the process space 433. The first array of openings 448 and the second array of openings 444 can be arranged, distributed or sized as described above.

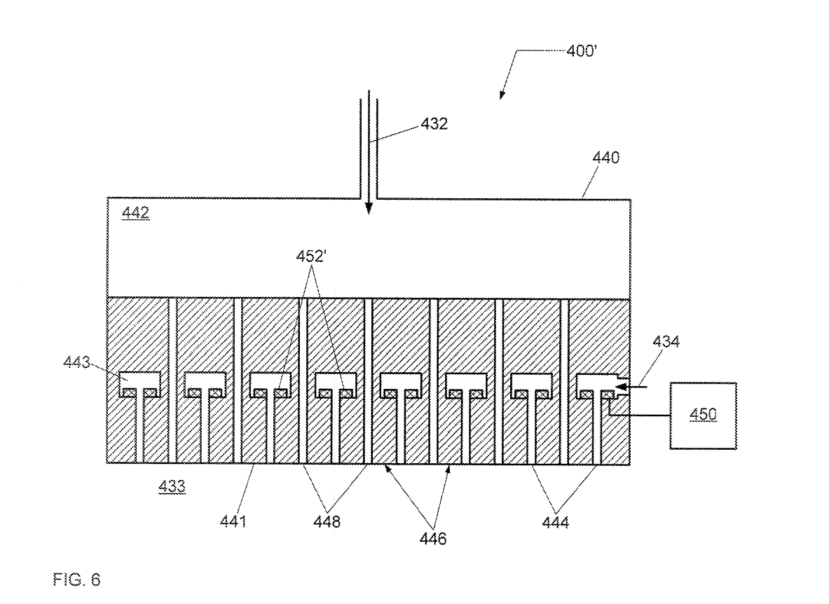

Furthermore, the gas distribution system 400 comprises a heat source having one or more heating elements 452 coupled to a power source 450. The one or more heating elements 452 are disposed on at least one interior surface of the gas distribution system 400, such that they may interact with the second composition 434 in the second plenum 443. For example, as illustrated in FIG. 5, the one or more heating elements 452 may be formed on an upper surface of the second plenum 443. The one or more heating elements 452 may be formed in a serpentine-like path, or a spiral-like path, or any arbitrary shape. Alternatively, for example, as illustrated in FIG. 6 in gas distribution system 400′, the one or more heating elements 452′ may be formed on a lower surface of the second plenum 443 surrounding the second array of openings 444. The one or more heating elements 452′ may be formed in a serpentine-like path, or a spiral-like path, or any arbitrary shape, and the one or more openings may be formed there through. Additionally, for example, the one or more heating elements 452, 452′ can comprise one or more resistive heating elements. When the power source 450 couples electrical power to the one or more heating elements 452, the one or more heating elements 452 may be elevated to a temperature sufficient to pyrolize one or more constituents of the second composition 434. Power source 450 may include a direct current (DC) power source, or it may include an alternating current (AC) power source.

The first composition 432 can include one or more constituents of the film forming composition wherein interaction with the heat source 450 is not desired. Additionally, the second composition 434 can include one or more constituents of the film forming composition wherein interaction with the heat source 450 is desired. For example, the first composition 432 can include one or more film forming gases and the second composition 434 can include an initiator. While the one or more film forming gases are introduced to process space 433, the initiator undergoes pyrolysis prior to introduction to process space 433. Once the one or more film forming gases and the initiator radicals interact in process space 433, the initiator radicals can catalyze the dissociation of at least one constituent of the one or more film forming gases.

As described above, the one or more heating elements 452, 4527 are disposed on at least one interior surface of the gas distribution system 400, 400′. such that they may Interact with any constituent of the film forming composition, or all of the constituents of the film forming composition including the optional initiator. An interior surface on the gas distribution system 400, 400′ can include any surface on the gas distribution system 400, 400′. As shown in FIG. 5, an interior surface can include the upper surface of the second plenum 443. As shown in FIG. 6, an interior surface can include the lower surface of the second plenum 443. However, the interior surface can further include a surface on housing 440 or within first plenum 442 that interacts with the film forming composition, or any surface within second plenum 443 that interacts with the film forming composition, or an internal surface of the inlet lines that provide the film forming composition 432 and the optional initiator 434 into first plenum 442 and second plenum 443. Additionally, the interior surface can include the upper surface of multi-component gas distribution plate 441, a surface of the first array of openings 448, a surface of the second array of openings 444, or the lower surface of the multi-component gas distribution plate 441, or a combination of two or more thereof. Furthermore, the one or more heating elements can be formed within any component of the gas distribution system 400, 400′ including, for example, the housing 440 and the multi-component gas distribution plate 441.

Although, the gas distribution systems shown in FIGS. 2 through 5 illustrate a single zone, the gas distribution systems can be multiple zones. For example, the gas distribution system can be configured to alter the amount of film forming composition introduced near tie center of the substrate relative to the amount of film forming composition introduced near the edge of the substrate.

Additionally, although the gas distribution systems shown in FIGS. 1 through 5 illustrate the processing of a substrate oriented in a horizontal plane, the gas distribution system can be configured to distribute a film forming composition to a substrate oriented in a vertical plane. Furthermore, although the gas distribution systems shown in FIGS. 1 through 5 illustrate the processing of a substrate, the gas distribution system can be configured to distribute a film forming composition to a plurality of substrates. For example, a plurality of substrates can be oriented in a horizontal plane, or the plurality of substrate can be arranged parallel to one another in a vertical direction.

According to one embodiment, the one or more heating elements comprise a resistive heating element. According to another embodiment, the one or more heating elements comprise a resistive film heating element. According to another embodiment, the one or more heating elements comprise a heating element that is thermally insulated from the gas distribution system. According to another embodiment, the one or more heating elements comprise a heating element in thermal contact with the gas distribution system. According to another embodiment, the one or more heating elements are coupled to at least one interior surface of the gas distribution system. According to yet another embodiment, the one or more heating elements are embedded within the gas distribution system.

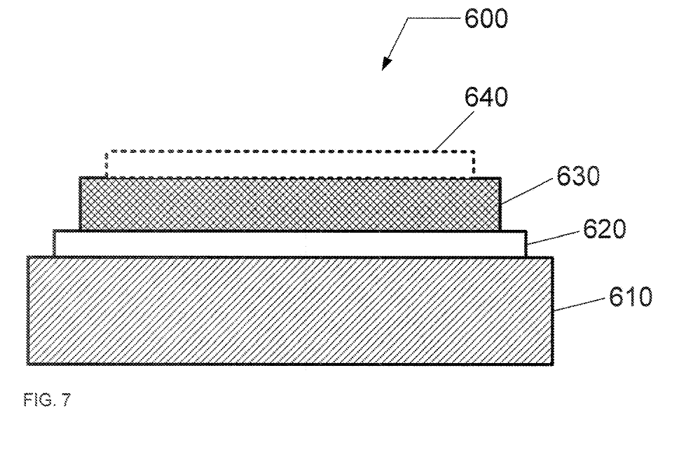

Referring now to FIG. 7, a cross-sectional view of a heating element is provided according to another embodiment. A multi-layer resistive film heating element 600 is shown comprising an insulation layer 620 formed on a component 610 having a surface exposed to the interior of a gas distribution system, a resistive heating layer 630 formed on the insulation layer 620, and a protective layer 640 formed on the resistive heating layer 630. For example, component 610 can include a gas distribution plate as described above.

The resistive heating layer 630 can comprise a resistive met,al or resistive metal alloy. For example the resistive heating layer 630 can comprise tungsten. nickel-chromium alloy, aluminum-iron alloy, aluminum nitride, etc. Examples of commercially available materials to fabricate resistive heating layers include Kanthal, Nikrothal, Akrothal, which are registered trademark names for metal alloys produced by Kanthal Corporation of Bethel, Conn. The Kanthal family includes ferritic alloys (FeCrAl) and the Nikrothal family includes austenitic alloys (NiCr, NiCrFe). The resistive heating layer 630 can be formed as a thick film using, for example, spray coating techniques, screen printing techniques, etc. For example, the thick film resistive heating layer 630 can be formed according to techniques commercially provided by Watlow (1310 Kingsland Dr., Batavia, Ill., 60510).

The insulation layer 620 can include a ceramic, plastic or polymer. For example, the insulation layer 620 can include quartz, silicon nitride, sapphire, or alumina, etc. Additionally, the protective layer 640 can include a ceramic, plastic, or polymer. For example, the protective layer 640 can include a spray coating, thermal spray coating or a plasma spray coating of a ceramic material applied over the resistive film heating layer 630.

Alternatively, a heating element can include a cartridge heater, a cast-in heater, a flexible heater, etc. commercially available from Watlow (1310 Kingsland Dr., Batavia, Ill., 60510).

Referring again to FIG. 1, the power source 50 is configured to provide electrical power to the one or more resistive film heating elements in the gas distribution system 40. For example, the power source 50 can be configured to deliver either DC power or AC power. Additionally, for example, the power source 50 can be configured to modulate the amplitude of the power, or pulse the power. Furthermore, for example, the power source 50 can be configured to perform at least one of setting, monitoring; adjusting or controlling a power, a voltage, or a current.

Referring still to FIG. 1, a temperature control system 22 can be coupled to the gas distribution system 40, the heat source 45, the process chamber 10 and/or the substrate holder 20, and configured to control the temperature of one or more of these components. The temperature control system 22 can include a temperature measurement system configured to measure the temperature of the gas distribution system 40 at one or more locations, the temperature of the heat source 45 at one or more locations, the temperature of the process chamber 10 at one or more locations and/or the temperature of the substrate holder 20 at one or more locations. The measurements of temperature can be used to adjust or control the temperature at one or more locations in deposition system 1.

The temperature measuring device, utilized by the temperature measurement system, can include an optical fiber thermometer, an optical pyrometer, a band-edge temperature measurement system as described in pending U.S. patent application Ser. No. 10/168544, filed on Jul. 2, 2002, the contents of which are incorporated herein by reference in their entirety, or a thermocouple such as a K-type thermocouple. Examples of optical thermometers include: an optical fiber thermometer commercially available from Advanced Energies, Inc., Model No. OR2000F; an optical fiber thermometer commercially available from Luxtron Corporation, Model No. M600; or an optical fiber thermometer commercially available from Takaoka Electric Mfg. Model No. FT-1420.

Alternatively, when measuring the temperature of one or more resistive heating elements, the electrical characteristics of each resistive heating element can be measured. For example, two or more of the voltage, current or power coupled to the one or more resistive heating elements can be monitored in order to measure the resistance of each resistive heating element. The variations of the element resistance can arise due to variations in temperature of the element which affects the element resistivity.

According to program instructions from the temperature control system 22 or the controller 80 or both, the power source 50 can be configured to operate the heat source 45, e.,g., the one or more heating elements, at a temperature ranging from approximately 100 degrees C. to approximately 600 degrees C. For example, the temperature can range from approximately 200 degrees C. to approximately 550 degrees C. The temperature can be selected based upon the film forming composition and, more particularly, the temperature can be selected based upon a constituent of the film forming composition.

Additionally, according to program instructions from the temperature control system 22 or the controller 80 or both, the temperature of the gas distribution system 40 can be set to a value approximately equal to or less than the temperature of the heat source 45, i.e., the one or more heating elements. For example, the temperature can be a value less than or equal to approximately 600 degrees C. Additionally, for example, the temperature can be a value less than approximately 550 degrees C. Further yet, for example, the temperature can range from approximately 30 degrees C. to approximately 550 degrees C. The temperature can be selected to be approximately equal to or less than the temperature of the one or more heating elements, and to be sufficiently high to prevent condensation which may or may not cause film formation on surfaces of the gas distribution system and reduce the accumulation of residue.

Additionally yet, according to program instructions from the temperature control system. 22 or the controller 80 or both, the temperature of the process chamber 10 can be set to a value less than the temperature of the heat source 45, i.e., the one or more heating elements. For example, the temperature can be a value less than approximately 200 degrees C. Additionally, for example, the temperature can be a value less than approximately 150 degrees C. Further yet, for example, the temperature can range from approximately 80 degrees C. to approximately 150 degrees C. However, the temperature may be the same or less than the temperature of the gas distribution system 40. The temperature can be selected to be less than the temperature of the one or more resistive film heating elements, and to be sufficiently high to prevent condensation which may or may not cause film formation on surfaces of the process chamber and reduce the accumulation of residue.

Once film forming composition enters the process space 33, the film forming composition adsorbs on the substrate surface, and film forming reactions proceed to produce a thin film on the substrate 25. According to program instructions from the temperature control system 22 or the controller 80 or both, the substrate holder 20 is configured to set the temperature of substrate 25 to a value less than the temperature of the heat source 45, the temperature of the gas distribution system 40, and the process chamber 10. For example, the substrate temperature can range up to approximately 80 degrees C. Additionally, the substrate temperature can be approximately room temperature. For example, the substrate temperature can range up to approximately 25 degrees C. However, the temperature may be less than or greater than room temperature.

The substrate holder 20 comprises one or more temperature control elements coupled to the temperature control system 22. The temperature control system 22 can include a substrate heating system, or a substrate cooling system, or both. For example, substrate holder 20 can include a substrate heating element or substrate cooling element (not shown) beneath the surface of the substrate holder 20. For instance, the heating system or cooling system can include a re-circulating fluid flow that receives heat from substrate holder 20 and transfers heat to a heat exchanger system (not shown) when cooling, or transfers heat from the heat exchanger system to the substrate holder 20 when heating. The cooling system or heating system may include heating/cooling elements; such as resistive heating elements, or thermoelectric heaters/coolers located within substrate holder 20. Additionally, the heating elements or cooling elements or both can be arranged in more than one separately controlled temperature zone. The substrate holder 20 may have two thermal zones including an inner zone and an outer zone. The temperatures of the zones may be controlled by heating or cooling the substrate holder thermal zones separately.

Additionally the substrate holder 20 comprises a substrate clamping system (e.g., electrical or mechanical clamping system) to clamp the substrate 25 to the upper surface of substrate holder 20. For example, substrate holder 20 may include an electrostatic chuck (ESC).

Furthermore, the substrate holder 20 can facilitate the delivery of heat transfer gas to the back-side of substrate 25 via a backside gas supply system to improve the gas-gap thermal conductance between substrate 25 and substrate holder 20. Such a system can be utilized when temperature control of the substrate is required at elevated or reduced temperatures. For example, the backside gas system can comprise a two-zone gas distribution system, wherein the backside gas (e.g., helium), pressure can be independently varied between the center and the edge of substrate 25.

Vacuum pumping system 60 can include a turbo-molecular vacuum pump (TMP) capable of a pumping speed up to approximately 5000 liters per second (and greater) and a gate valve for throttling the chamber pressure. For example, a 1000 to 3000 liter per second TMP can be employed. TMPs can be used for low pressure processing, typically less than approximately 1 Torr. For high pressure processing i.e., greater than approximately 1 Torr), a mechanical booster pump and dry roughing pump can be used. Furthermore, a device for monitoring chamber pressure (not shown) can be coupled to the process chamber 10. The pressure measuring device can be, for example, a Type 628B Baratron absolute capacitance manometer commercially available from MKS Instruments, Inc. (Andover, Mass.).

Resenting still to FIG. 1, the deposition system 1 can further comprise a controller 80 that comprises a microprocessor, memory, and a digital I/O port capable of generating control voltages sufficient to communicate and activate inputs to deposition system 1 as well as monitor outputs from deposition system Moreover, controller 80 can be coupled to and can exchange information with the process chamber 10, the substrate holder 20, the temperature control system 22, the film forming composition supply system 30, the gas distribution system 40, the heat source 45, and the vacuum pumping system 60, as well as the backside gas deliver, system (not shown), and/or the electrostatic clamping system (not shown). A program stored in the memory can be utilized to activate the inputs to the aforementioned components of deposition system 1 according to a process recipe in order to perform the method of depositing a thin film. One example of controller 80 is a DELL PRECISION WORKSTATION 610™ available from Dell Corporation, Austin, Tex.

Controller 80 may be locally located relative to the deposition system 1, or it may be remotely located relative to the deposition system 1 via an internet or intranet. Thus, controller 80 can exchange data with the deposition system 1 using at least one of a direct connection, an intranet, or the internet. Controller 80 may be coupled to an intranet at a customer site (i.e., a device maker, etc.), or coupled to an intranet at a vendor site (i.e., an equipment manufacturer). Furthermore, another computer (i.e. controller, server, etc.) can access controller 80 to exchange data via at least one of a direct connection, an intranet, or the internet.

The deposition system 1 can be periodically cleaned using an in-situ cleaning system (not shown) coupled to, for example, the process chamber 10 or the gas distribution system 40. Per a frequency determined by the operator, the in-situ cleaning system can perform routine cleanings of the deposition system 1 in order to remove accumulated residue on internal surfaces of deposition system 1. The in-situ cleaning system can, for example, comprise a radical generator configured to introduce chemical radical capable of chemically reacting and removing such residue. Additionally, for example, the in-situ cleaning system can, for example, include an ozone generator configured to introduce a partial pressure of ozone. For instance the radical generator can include an upstream plasma source configured to generate oxygen or fluorine radical from oxygen (O₂), nitrogen trifluoride (NF₃), O₃, XeF₂, ClF₃, or C₃F₈ (or, more generally, CₓF_{y}), respectively. The radical generator can include an ASTRON® reactive gas generator, commercially available from MKS Instruments, Inc. ASTeX® Products (90 Industrial Way, Wilmington, Mass. 01887).

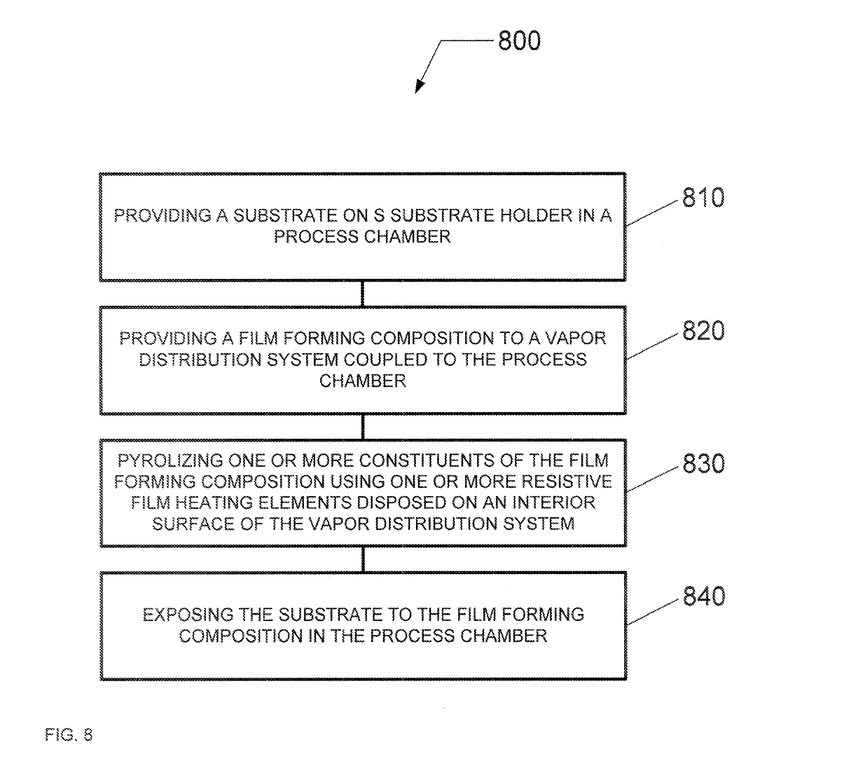

FIG. 8 illustrates a method of depositing a thin film on a substrate according to another embodiment. The method 800 includes, at 810, providing a substrate in a process chamber of a deposition system. For example, the deposition system can include the deposition system described above in FIG. 1. The substrate can, for example, be a Si substrate. A Si substrate can be of n- or p-type, depending on the type of device being formed. The substrate can be of any size, for example a 200 mm substrate, a 300 mm substrate, or an even larger substrate. According to an embodiment of the invention, the substrate can be a patterned substrate containing one or more vias or trenches, or combinations thereof.

At 820, a film forming composition is provided to a gas distribution system that is configured to introduce the film forming composition to the process chamber above the substrate. For example, the gas distribution system can be located above the substrate and opposing an upper surface of the substrate.

At 830, one or more constituents of the film forming composition are subjected to pyrolysis using one or more heating elements, such as one or more resistive film heating elements, disposed on an interior surface of the gas distribution system or embedded within the gas distribution system. The gas distribution system can be any one of the systems described in FIGS. 2 through 5 above, or any combination thereof,

At 840, the substrate is exposed to the film forming composition to facilitate the formation of the thin film. The temperature of the substrate can be set to a value less than the temperature of the one or more heating elements, e.g. one or more resistive film heating elements. For example, the temperature of the substrate can be approximately room temperature.

Although only certain exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

1. A processing system for depositing a thin film on a substrate, comprising;
a process chamber having a pumping system configured to evacuate said process chamber;
a substrate holder coupled to said process chamber and configured to support said substrate;
a gas distribution system coupled to said process chamber and configured to introduce a film forming composition to a process space in the vicinity of a surface of said substrate; and
a heat source coupled to the gas distribution system, said heat source comprising one or more heating elements coupled to a power source, wherein said one or more heating elements are disposed on an interior surface of said gas distribution system or embedded within said gas distribution system or both, and configured to interact with said film forming composition and cause pyrolysis of one or more constituents of said film forming composition when heated.

2. The processing system of claim 1, wherein said power source comprises a DC power source or an AC power source.

3. The processing system of claim 1, wherein said one or more heating elements comprises a resistive metal, a resistive metal alloy, a resistive metal nitride, or a combination of two or more thereof.

4. The processing system of claim 1, wherein an insulation layer is disposed between said one or more heating elements and the surface upon which the one or more heating elements are formed.

5. The processing system of claim 1, wherein a protective layer is formed over said one or more heating elements.

6. The Processing system of claim 1, wherein said gas distribution system comprises:
a housing configured to be coupled to said process chamber; and
a gas distribution plate coupled to said housing and configured to form a plenum between said housing and said process chamber, wherein said plenum is configured to receive said film forming composition and introduce said film forming composition to said process space through a plurality of openings formed in said gas distribution plate.

7. The processing system of claim 6, wherein said one or more heating elements are formed on an upper surface of said gas distribution plate.

8. The processing system of claim 7, wherein said one or more heating elements are formed in a serpentine-like pattern on an upper surface of said gas distribution plate, or a spiral-like pattern on an upper surface of said gas distribution plate, or a combination thereof.

9. The processing system of claim 6, wherein said housing forms a single zone plenum.

10. The processing system of claim 6, wherein said housing forms a multi-zone plenum.

11. The processing system of claim 6, wherein said plurality of openings is formed uniformly over said gas distribution plate.

12. The processing system of claim 6, wherein said plurality of openings is formed non-uniformly over said gas distribution plate.

13. The processing system of claim 6, wherein said gas distribution system further comprises:
an intermediate gas distribution plate having a plurality of openings formed there through that is coupled to said housing between said housing and said gas distribution plate, wherein a flow of said film forming composition introduced to said plenum above said intermediate gas distribution plate flows through said intermediate gas distribution plate into an intermediate plenum before entering said process space through said gas distribution plate.

14. The processing system of claim 13, wherein said one or more heating elements are formed on an upper surface of said intermediate gas distribution plate.

15. The processing system of claim 13, wherein said one or more heating elements are formed on an upper surface of said gas distribution plate.

16. The processing system of claim 15, wherein said one or more openings in said intermediate gas distribution plate are arranged such that a flow of said film forming composition through said intermediate gas distribution plate impinges on said one or more heating elements.

17. The processing system of claim 13, wherein said one or more heating elements are formed on a lower surface of said intermediate gas distribution plate.

18. The processing system of claim 6, wherein said one or more heating elements are formed on a surface of one or more of said plurality of openings formed in said gas distribution plate.

19. The processing system of claim 13, wherein said one or more heating elements are formed on a surface of one or more of said plurality of openings formed in said intermediate gas distribution plate.

20. The processing system of claim 1, wherein said gas distribution system comprises:
a housing configured to be coupled to said process chamber; and
a multi-component gas distribution plate coupled to said housing and configured to independently couple a first composition from a first plenum through a first array of openings to said process space and a second composition from a second plenum through a second array of openings to said process space without mixing said first composition and said second composition prior to said process space.

21. The processing system of claim 20, wherein said one or more heating elements are coupled to an interior surface of said first plenum, or an interior surface of said second plenum, or an interior surface of both said first plenum and said second plenum.

22. The processing system of claim 20, wherein said first composition comprises a film forming precursor, said second composition comprises an initiator, and said one or more heating elements are formed on an interior surface of said second plenum.

23. The processing system of claim 1, wherein said substrate holder is configured to control the temperature of said substrate.

24. The processing system of claim 1, wherein said substrate holder is configured to support a plurality of substrates, and said gas distribution system introduces said film forming composition in the vicinity of a surface of each of said plurality of substrates.

25. A gas distribution system configured to be coupled to a processing system for depositing a thin film on a substrate, comprising:
a heat source coupled to said gas distribution system, said heat source comprising one or more resistive film heating elements coupled to a power source, wherein said one or more resistive film heating elements are disposed on an interior surface of said gas distribution system and configured to interact with a film forming composition and cause pyrolysis of one or more constituents of said film forming composition when heated.

26. A method of depositing a thin film on a substrate, the method comprising:
providing a substrate on a substrate holder in a process chamber of a deposition system;
providing a film forming composition to a gas distribution system located above said substrate and opposing an upper surface of said substrate;
pyrolizing one or more constituents of said film forming composition using one or more heating elements disposed on an interior surface of said gas distribution system; and
exposing said substrate to said film forming composition in said process chamber.

27. The method of claim 26, further comprising:
setting the temperature of said substrate holder to a temperature less than the temperature of said gas distribution system.
